(19) United States
(12) Patent Application Publication
(10) Pub. No.: US 2024/0360552 A1
(43) Pub. Date: Oct. 31, 2024

(54) SUBSTRATE PROCESSING APPARATUS, METHOD OF MANUFACTURING SEMICONDUCTOR DEVICE, AND RECORDING MEDIUM

(71) Applicant: Kokusai Electric Corporation, Tokyo (JP)

(72) Inventors: Hideharu ITATANI, Toyama-shi (JP); Toshiyuki Kikuchi, Toyama-shi (JP)

(73) Assignee: Kokusai Electric Corporation, Tokyo (JP)

(21) Appl. No.: 18/613,747

(22) Filed: Mar. 22, 2024

(30) Foreign Application Priority Data
Apr. 28, 2023 (JP) 2023-074631

(51) Int. Cl. C23C 16/44; C23C 16/52; H01L 21/02

(52) U.S. Cl. CPC C23C 16/4412; C23C 16/52; H01L 21/02164; H01L 21/02271

(57) ABSTRACT

A technique that includes: a processing container in which a substrate is processed; a processing gas supplier that supplies a processing gas with which the substrate is processed; a processing gas supply pipe that is connected to the processing gas supplier and the processing container and through which the processing gas is supplied to the processing container, an exhauster that is provided on the processing gas supply pipe; and a controller for controlling the exhauster to discharges a remaining gas in the processing gas supply pipe out of the processing gas supply pipe.

### CROSS-REFERENCE TO RELATED APPLICATIONS

This application is based upon and claims the benefit of priority from Japanese Patent Application No. 2023-074631, filed on Apr. 28, 2023, the entire contents of which are incorporated herein by reference.

### FIELD

The present disclosure relates to a substrate processing apparatus, a method of manufacturing a semiconductor device, and a recording medium.

### DESCRIPTION OF THE RELATED ART

A substrate processing apparatus has been used for processing a substrate in a semiconductor device manufacturing process. In this substrate processing apparatus, a substrate is placed in a processing space where the substrate is processed. In processing the substrate, a processing gas is supplied into the processing space. The substrate processing apparatus includes an exhauster that discharges the processing gas out of the processing space.

According to the foregoing technique, there is a possibility that a processing gas remains in a processing gas supply pipe through which the processing gas is supplied to a processing container, to thereby exert an adverse effect in processing a substrate.

### SUMMARY

The present disclosure provides a technique capable of reducing an adverse effect of a processing gas that remains in a processing gas supply pipe, in a substrate processing apparatus for processing a substrate, using the processing gas.

According to an embodiment of the present disclosure, there is provided a technique that includes: a processing container in which a substrate is processed; a processing gas supplier that supplies a processing gas with which the substrate is processed; a processing gas supply pipe that is connected to the processing gas supplier and the processing container and through which the processing gas is supplied to the processing container; an exhauster that is provided on the processing gas supply pipe; and a controller for controlling the exhauster to discharges a remaining gas in the processing gas supply pipe out of the processing gas supply pipe.

### BRIEF DESCRIPTION OF THE DRAWINGS

FIG. 1 is a diagram illustrating a substrate processing apparatus according to an embodiment of the present disclosure.

FIG. 2 is a block diagram illustrating a controller of the substrate processing apparatus according to the embodiment of the present disclosure.

FIG. 3 is a diagram illustrating a gas supplier of the substrate processing apparatus according to the embodiment of the present disclosure.

FIG. 4 is a diagram subsequent to FIG. 3 and illustrating the gas supplier of the substrate processing apparatus according to the embodiment of the present disclosure.

FIG. 5 is a diagram subsequent to FIG. 4 and illustrating the gas supplier of the substrate processing apparatus according to the embodiment of the present disclosure.

FIG. 6 is a diagram subsequent to FIG. 5 and illustrating the gas supplier of the substrate processing apparatus according to the embodiment of the present disclosure.

### DETAILED DESCRIPTION

One or more embodiments will be described below with reference to the drawings. In the following, identical constituents are denoted by the same reference sign; therefore, the repeated description thereof may be omitted. It should be noted that the drawings each may present a schematic illustration rather than an actual illustration for a better understanding of the following description. It is understood that each illustration is merely exemplary and is not intended to limit the interpretation of the present disclosure. In the drawings, moreover, a dimensional relationship between the constituents, a ratio between the constituents, and others are not necessarily equal to actual ones. With regard to two figures optionally selected from among the drawings, a dimensional relationship between the constituents, a ratio between the constituents, and others illustrated in one of the figures are not necessarily equal to those illustrated in the other figure.

### (Outline of Substrate Processing Apparatus)

A substrate processing apparatus to be described in one or more embodiments is used in a semiconductor device manufacturing process. A substrate is subjected to processing in a processing chamber with the substrate heated by a heater or the like. A non-limiting example of the substrate to be subjected to the processing by the substrate processing apparatus may be a semiconductor wafer substrate on which a semiconductor device is fabricated (hereinafter, simply referred to as a “wafer”). Examples of the processing to be performed by the substrate processing apparatus may include, but not limited to, oxidization; diffusion; reflow and annealing for carrier activation and planarization after ion implantation; and film formation by thermal chemical vapor deposition (CVD) reaction.

### (Configuration)

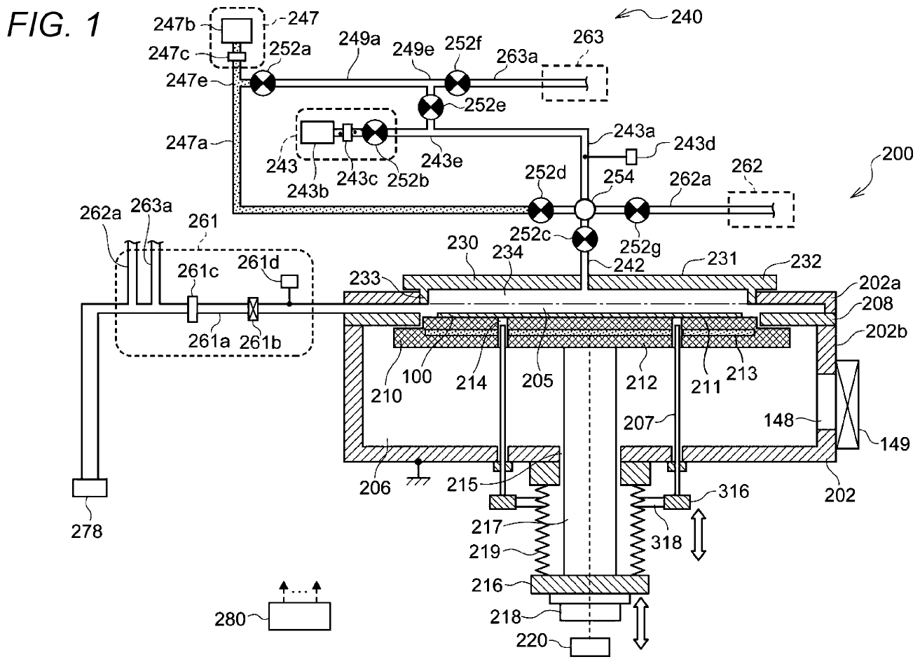

With reference to FIG. 1, next, a description will be given of an exemplary schematic configuration of a substrate processing apparatus to be suitably used in an embodiment of the present disclosure. FIG. 1 is a diagram illustrating a substrate processing apparatus to be suitably used in an embodiment of the present disclosure.

### (Entire Apparatus)

A substrate processing apparatus 200 includes a processing container 202 in which a substrate 100 is processed. The processing container 202 is, for example, a hermetically sealed flat container having a circular cross section. The processing container 202 is made of, for example, a metal material such as aluminum (Al) or stainless steel (SUS). The processing container 202 has a processing space 205 and a transfer space 206 each defined in the processing container 202. In the processing space 205, the substrate 100, such as a silicon substrate, is processed. In transferring the substrate 100 to the processing space 205, the substrate 100 passes through the transfer space 206. The processing container 202 includes an upper container 202a and a lower container 202b. A partition 208 is provided between the upper container 202a and the lower container 202b.

The lower container 202b has a substrate loading/unloading port 148 formed in a side surface of the lower container 202b. The substrate loading/unloading port 148 is adjacent to a gate valve 149. The substrate 100 travels between the lower container 202b and a vacuum transfer chamber (not illustrated) through the substrate loading/unloading port 148. A plurality of lifting pins 207 are provided on a bottom side of the lower container 202b. In addition, the lower container 202b is grounded.

The processing space 205 is constituted of a processing chamber that is defined by, for example, a susceptor 212 and a shower head 230. In the processing space 205, a substrate mount 210 is provided, on which the substrate 100 is mounted. The substrate mount 210 mainly includes a substrate mount surface 211 on which the substrate 100 is mounted, the susceptor 212 of which a surface corresponds to the substrate mount surface 211, and a heater 213 incorporated in the susceptor 212. The heater 213 serves as a heat source. The susceptor 212 has a plurality of through-holes 214 through which the lifting pins 207 pass. The through-holes 214 are formed in one-to-one correspondence with the lifting pins 207. The heater 213 is connected to a temperature controller 220 that controls a temperature of the heater 213.

The susceptor 212 is supported by a shaft 217. The shaft 217 includes a support. The support passes through a hole 215 formed in a bottom wall of the processing container 202. Moreover, the support is connected to a lifter 218 outside the processing container 202 with a support plate 216 interposed between the support and the lifter 218. The lifter 218 is a drive system and serves as a first lifter. The lifter 218 operates to lift the shaft 217 and the susceptor 212 up and down. The substrate 100 on the substrate mount surface 211 can thus be lifted up and down. The shaft 217 has a lower end covered with a bellows 219. The interior of the processing container 202 is hermetically kept.

In transferring the substrate 100, the susceptor 212 is lifted down to a position where the substrate mount surface 211 is opposite the substrate loading/unloading port 148 (this position will be referred to as a substrate transfer position). In processing the substrate 100, the susceptor 212 is lifted up so that the substrate 100 is at a substrate processing position in the processing space 205 as illustrated in FIG. 1.

The lifting pins 207 are connected to a lifter 318 outside the processing container 202 with support plates 316 interposed between the lifting pins 207 and the lifter 318. The lifter 318 is a drive system and serves as a second lifter. The lifter 318 operates to lift the lifting pins 207 up and down. Distal ends of the lifting pins 207 thus protrude upward from the substrate mount surface 211 to support the substrate 100 from below. The lifter 318 also operates to cause the distal ends of the lifting pins 207 to retract into the through-holes 214, so that the through-holes 214 are closed with the distal ends of the lifting pins 207.

Specifically, when the susceptor 212 is lifted down to the substrate transfer position, upper ends of the lifting pins 207 protrude upward from the substrate mount surface 211 to support the substrate 100 from below. When the susceptor 212 is lifted up to the substrate processing position as illustrated in FIG. 1, the distal ends of the lifting pins 207 retract into the through-holes 214 in the susceptor 212 where the lifting pins 207 are not in contact with the substrate 100. The through-holes 214 in the susceptor 212 are thus closed with the distal ends of the lifting pins 207. In other words, the distal ends of the lifting pins 207, which have protruded upward from the substrate mount surface 211, retract into the through-holes 214, so that the substrate mount surface 211 supports the back surface of the substrate 100 from below.

The shower head 230 is provided above (i.e., upstream of) the processing space 205. The shower head 230 includes a lid 231. The lid 231 has a flange 232. The flange 232 is supported on the upper container 202a. The lid 231 also has a positioner 233. The lid 231 is secured with the positioner 233 fitted into the upper container 202a.

The shower head 230 has a buffer space 234. The buffer space 234 is defined by the lid 231 and the positioner 233. The buffer space 234 communicates with the processing space 205. When a gas is supplied into the buffer space 234, the gas is diffused inside the buffer space 234, and then is uniformly supplied into the processing space 205. In the present embodiment, the buffer space 234 and the processing space 205 are provided separately; however, the present disclosure is not limited thereto. For example, the buffer space 234 may be defined in the processing space 205.

The processing space 205 is mainly defined by the upper container 202a and an upper structure of the susceptor 212 at the substrate processing position. A structure that constitutes the buffer space 234 and the processing space 205 is referred to as the processing chamber. In the present embodiment, the processing chamber includes the shower head 230. As a matter of course, the structure of the processing chamber is not limited to that described above as long as the processing chamber constitutes the processing space 205.

The transfer space 206 is mainly defined by the lower container 202b and a lower structure of the susceptor 212 at the substrate processing position. A structure that constitutes the transfer space 206 is referred to as a transfer chamber. The transfer chamber is located below the processing chamber. As a matter of course, the structure of the transfer chamber is not limited to that described above as long as the transfer chamber constitutes the transfer space 206.

### (Gas Supplier)

Next, a description will be given of a gas supplier 240. The gas supplier 240 includes a processing gas supplier 243, an inert gas supplier 247, a bypass pipe 249a, a first exhauster 262, and a second exhauster 263. A common gas supply pipe 242 is connected to a processing gas supply pipe 243a, an inert gas supply pipe 247a, and a first processing gas exhaust pipe 262a via a connector 254.

The common gas supply pipe 242 is provided with a third valve 252c that is located between the common gas supply pipe 242 and the connector 254. When the third valve 252c is opened, a gas flows from the connector 254 toward the processing container 202 through the common gas supply pipe 242. When a pressure inside the connector 254 is lower than a pressure inside the processing container 202, the gas flows from the processing container 202 toward the connector 254 through the common gas supply pipe 242.

In the present embodiment, the connector 254 is located nearer to the shower head 230 than to the processing gas supplier 243, in pipes including the processing gas supply pipe 243a and the common gas supply pipe 242. In the present embodiment, the position of the connector 254 that is nearer to the shower head 230 refers to, for example, a position where a pressure loss owing to a pipe wear resistance occurring from a second valve 252b (to be described later) to the connector 254 becomes substantially equal to a pressure loss owing to a pipe wear resistance occurring from the connector 254 to the shower head 230. This is because the processing gas supply pipe 243a is typically larger in inner diameter (smaller in flow path resistance) and therefore larger in conductance than a pipe portion of the shower head 230. For this reason, in order to make the pressure loss owing to the pipe wear resistance occurring from the second valve 252b to the connector 254 equal to the pressure loss owing to the pipe wear resistance occurring from the connector 254 to the shower head 230, the connector 254 is located nearer to the shower head 230. The processing gas supplier 243 including the processing gas supply pipe 243a mainly supplies a processing gas with which the substrate 100 is processed, and the inert gas supplier 247 mainly supplies an inert gas.

### (Processing Gas Supplier and Processing Gas Supply Pipe)

The processing gas supplier 243 is connected to the processing gas supply pipe 243a. The processing gas supplier 243 includes a mass flow controller (MFC) 243c serving as a flow rate controller, and the second valve 252b serving as an opening degree regulating valve. The processing gas supply pipe 243a is provided with a processing gas supply source 243b, the MFC 243c, and the second valve 252b that are arranged in this order from the upstream side. It should be noted that the processing gas supplier 243 may include the processing gas supply source 243b.

The processing gas supply pipe 243a is connected to the connector 254. The processing gas from the processing gas supplier 243 is thus supplied into the shower head 230 through the common gas supply pipe 242.

The processing gas supply source 243b generates, for example, an oxide gas, and supplies the oxide gas to the MFC 243c. For example, an oxygen (O)- and hydrogen (H)-containing gas is usable as an oxidant (oxide gas). Examples of the O- and H-containing gas may include, but not limited to, water vapor (H₂O gas), a hydrogen peroxide (H₂O₂) gas, a combination of a hydrogen (H₂) gas and an oxygen (O₂) gas, and a combination of a H₂ gas and an ozone (O₃) gas. The oxidant may be, for example, an oxygen (O)-containing gas in addition to the O- and H-containing gas. Examples of the O-containing gas may include, but not limited to, an O₂ gas, an O₃ gas, a nitrous oxide (N₂O) gas, a nitrogen monoxide (NO) gas, a nitrogen dioxide (NO₂) gas, a carbon monoxide (CO) gas, and a carbon dioxide (CO₂) gas. It should be noted that the O- and H-containing gas is also a kind of the O-containing gas. One or more O-containing gases selected from those described above are usable as the oxidant. The present embodiment describes, as an example, a case where the processing gas supply source 243b supplies a raw material gas rather than a carrier gas.

The processing gas supply pipe 243a is also provided with a branch portion 243e and a sensor 243d. The branch portion 243e is placed downstream of the processing gas supplier 243, and is connected to the bypass pipe 249a (to be described later).

The sensor 243d senses a concentration of the processing gas in the processing gas supply pipe 243a. In other words, the sensor 243d senses a gas remaining in the processing gas supply pipe 243a. The sensor 243d notifies a controller 280 of the concentration of the processing gas in the processing gas supply pipe 243a.

### (Inert Gas Supplier and Inert Gas Supply Pipe)

The inert gas supplier 247 is connected to the inert gas supply pipe 247a, and includes a mass flow controller (MFC) 247c serving as a flow rate controller. The inert gas supply pipe 247a is provided with an inert gas supply source 247b and the MFC 247c that are arranged in this order from the upstream side. It should be noted that the inert gas supplier 247 may include the inert gas supply source 247b.

The inert gas supply source 247b supplies an inert gas. The inert gas is, for example, a nitrogen (N₂) gas.

The inert gas supply pipe 247a is connected to the connector 254 via a fourth valve 252d. The inert gas from the inert gas supplier 247 is thus supplied into the shower head 230 through the common gas supply pipe 242.

The inert gas from the inert gas supply source 247b is higher in pressure than the processing gas from the processing gas supply source 243b. Moreover, the inert gas supplied to the connector 254 is higher in pressure than the processing gas. The inert gas from the inert gas supply source 247b acts as a purge gas for purging the gas remaining in the processing container 202 and shower head 230 in a substrate processing process.

The inert gas supply pipe 247a is also provided with a branch portion 247e. The branch portion 247e is placed downstream of the inert gas supplier 247, and is connected to the bypass pipe 249a (to be described later).

### (Bypass Pipe)

The bypass pipe 249a is provided with a first valve 252a, a fifth valve 252e, a sixth valve 252f, and a branch portion 249e. The bypass pipe 249a is connected to the branch portion 247e on the inert gas supply pipe 247a via the first valve 252a. The bypass pipe 249a is also connected to the branch portion 243e on the processing gas supply pipe 243a via the fifth valve 252e. The bypass pipe 249a is also connected to the second exhauster 263 (to be described later) via the sixth valve 252f. The first valve 252a, the fifth valve 252e, and the sixth valve 252f are provided on the bypass pipe 249a with the branch portion 249e in between. In other words, the bypass pipe 249a is branched in three directions by the branch portion 249e.

### (First Exhauster)

The first exhauster 262 is connected to the connector 254. The first exhauster 262 discharges the gas out of the pipes of the gas supplier 240. In other words, the first exhauster 262 is provided on the processing gas supply pipe 243a. The first exhauster 262 is an example of an exhauster according to the present disclosure.

More specifically, the first exhauster 262 includes the first processing gas exhaust pipe 262a that is an example of a processing gas exhaust pipe. The first processing gas exhaust pipe 262a has one end connected to the connector 254 and another end connected to a processing chamber exhauster 261 (to be described later). The first processing gas exhaust pipe 262a is provided with a seventh valve 252g.

The first processing gas exhaust pipe 262a is connected to the connector 254 via the seventh valve 252g. When the seventh valve 252g is opened, the gas in the pipes of the gas supplier 240 flows from the connector 254 into the first processing gas exhaust pipe 262a. The first processing gas exhaust pipe 262a is made of a metal, and has an inner wall subjected to anticorrosion processing.

In the present embodiment, the first exhauster 262 is capable of discharging a remaining gas that remains in the processing space 205 out of the processing space 205. The seventh valve 252g is made of a material capable of resisting a high temperature of the processing gas heated in the shower head 230 as will be described later.

As described above, the first processing gas exhaust pipe 262a is connected to the connector 254, and the connector 254 is provided near the shower head 230 in the pipes including the processing gas supply pipe 243a and the common gas supply pipe 242. In the present embodiment, the first exhauster 262 is provided near the shower head 230 in the pipes including the processing gas supply pipe 243a and the common gas supply pipe 242.

### (Second Exhauster)

The second exhauster 263 is connected to the bypass pipe 249a. The second exhauster 263 discharges the gas out of the pipes of the gas supplier 240.

More specifically, the second exhauster 263 includes a second processing gas exhaust pipe 263a that is connected to the processing chamber exhauster 261 (to be described later). The second processing gas exhaust pipe 263a is provided with a sixth valve 252f. The second processing gas exhaust pipe 263a is made of a metal, and has an inner wall that is subjected to anticorrosion processing.

The second processing gas exhaust pipe 263a is connected to the bypass pipe 249a via the sixth valve 252f. When the sixth valve 252f is opened, the gas in the pipes of the gas supplier 240 flows from the bypass pipe 249a into the second processing gas exhaust pipe 263a. The sixth valve 252f is made of a material capable of resisting a high temperature of the processing gas heated in the shower head 230 as will be described later.

In the present embodiment, the second valve 252b is, for example, an opening degree regulating valve. Also in the present embodiment, each of the valves of the gas supplier 240, excluding the second valve 252b, is, for example, an on-off valve. In the following description, in a case where the first to seventh valves 252a to 252g are not particularly distinguished from each other, the first to seventh valves 252a to 252g are collectively referred to as valves 252.

### (Exhauster)

An exhauster that discharges an atmosphere out of the processing container 202 is mainly constituted of the processing chamber exhauster 261. The processing chamber exhauster 261 discharges an atmosphere out of the processing space 205.

The processing chamber exhauster 261 includes an exhaust pipe 261a, a valve 261b, an auto-pressure controller (APC) 261c, and a pressure detector 261d. The exhaust pipe 261a communicates with the processing space 205. The exhaust pipe 261a is provided with the APC 261c and the pressure detector 261d. The APC 261c is a pressure controller that regulates a pressure in the processing space 205 to a predetermined value. The pressure detector 261d measures the pressure in the processing space 205. The APC 261c includes a valve body (not illustrated) having a regulatable opening degree. The APC 261c regulates a conductance of the exhaust pipe 261a in accordance with an instruction from the controller 280 (to be described later). On the exhaust pipe 261a, the valve 261b is provided upstream of the APC 261c.

A dry pump (DP) 278 is provided downstream of the exhaust pipe 261a. The DP 278 discharges the atmosphere out of the processing space 205 through the exhaust pipe 261a.

In the present embodiment, the processing chamber exhauster 261 is connected to the first exhauster 262 and the second exhauster 263. More specifically, as illustrated in FIG. 1, the first processing gas exhaust pipe 262a and the second processing gas exhaust pipe 263a are connected to the exhaust pipe 261a at a position downstream of the APC 261c. It should be noted that FIG. 1 partially illustrates the first processing gas exhaust pipe 262a and the second processing gas exhaust pipe 263a.

In the present embodiment, as described above, the DP 278 is connected to the first processing gas exhaust pipe 262a and the second processing gas exhaust pipe 263a via the exhaust pipe 261a. Therefore, the DP 278 discharges the gas out of the pipes of the gas supplier 240 through the first processing gas exhaust pipe 262a and the second processing gas exhaust pipe 263a.

### (Controller)

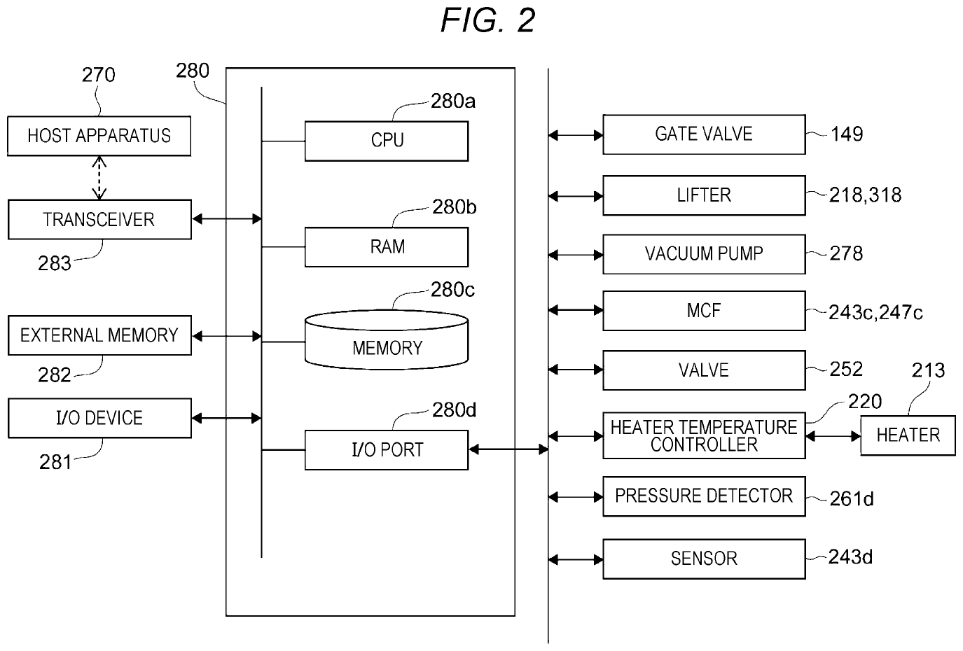

With reference to FIG. 2, next, a description will be given of the controller 280 that is an example of a controller in the present embodiment and controls operation of each constituent of the substrate processing apparatus 200. FIG. 2 illustrates the controller of the substrate processing apparatus according to the embodiment of the present disclosure.

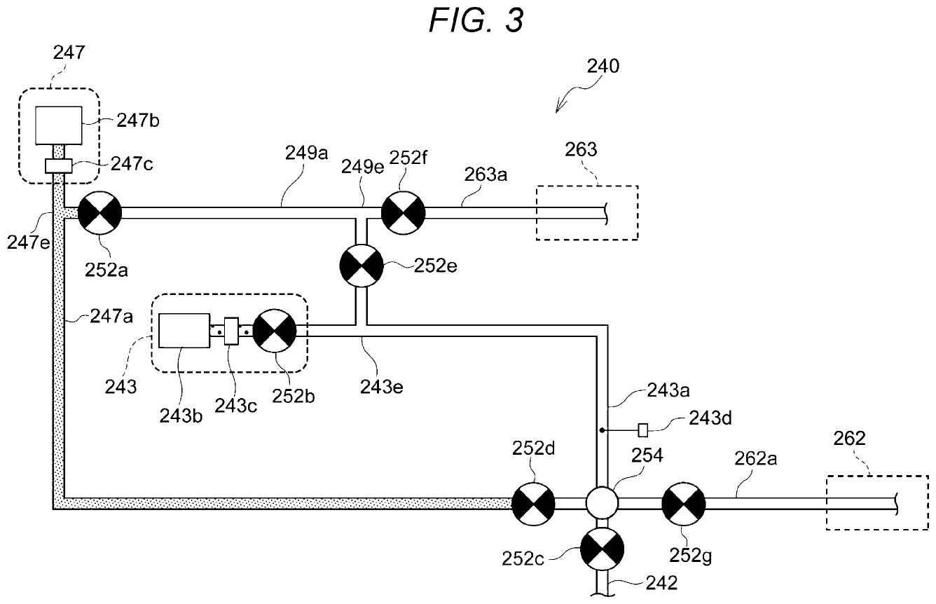

The substrate processing apparatus 200 includes the controller 280 that controls the operation of each constituent of the substrate processing apparatus 200. As illustrated in FIG. 2, the controller 280 includes at least a processor (CPU) 280a, a transitory memory (RAM) 280b, a memory 280c, and an I/O port 280d. The controller 280 is connected to each constituent of the substrate processing apparatus 200 via the I/O port 280d. The controller 280 invokes a program or a recipe from the memory 280c via a transceiver 283 in accordance with an instruction from a host controller (a host apparatus) 270 or a user. The controller 280 controls the operation of each constituent in accordance with the contents of the invoked program or recipe. The constituents of the substrate processing apparatus 200 include the lifters 218 and 318. The controller 280 is configured to be capable of controlling the operation of each of the lifters 218 and 318 by executing a program describing procedures for carrying out steps (from a substrate loading step to a substrate unloading step) illustrated in FIGS. 3 to 6.

The controller 280 is also connected to the processing chamber exhauster 261 and the valve 252. That is, the controller 280 is configured to be capable of controlling the operation of each of the processing chamber exhauster 261 and the valve 252 by executing the program describing the procedures for carrying out the steps (from the substrate loading step to the substrate unloading step) illustrated in FIGS. 3 to 6. In other words, the controller 280 is capable of controlling the first exhauster 262 so that the first exhauster 262 discharges the remaining gas remaining in the processing gas supply pipe 243a out of the processing gas supply pipe 243a. The controller 280 is also capable of controlling the processing chamber exhauster 261 so that the processing chamber exhauster 261 discharges the remaining gas remaining in the processing container 202 out of the processing container 202.

The controller 280 is also connected to the sensor 243d. The controller 280 measures a concentration of the gas in the processing gas supply pipe 243a.

The controller 280 also measures a remaining gas exhaust time during which the gas is discharged out of the pipes of the gas supplier 240 in each step (to be described later). More specifically, the CPU 280a measures a time from a start to an end of exhaust processing performed by the controller 280. The CPU 280a then acquires a threshold value set in advance and stored in the memory 280c, and compares the remaining gas exhaust time with the threshold value. When the remaining gas exhaust time is longer than the threshold value, the CPU 280a determines that unusual exhaust has occurred.

In the present embodiment, the controller 280 is connected to an I/O device 281 such as a touch panel. The I/O device 281 has a function of displaying information output from the controller 280. The controller 280 performs control to cause, in response to the determination by the CPU 280a that the unusual exhaust has occurred, the I/O device 281 to display information about the occurrence of the unusual exhaust. In the present embodiment, the I/O device 281 is an example of a display, and displaying information about the occurrence of the unusual exhaust is an example of providing a notification.

In the present embodiment, the controller 280 records the unusual exhaust on the memory 280c in response to the determination that the unusual exhaust has occurred. In other words, the memory 280c stores a history of the unusual exhaust in accordance with a notification about the unusual exhaust from the controller 280.

In the present embodiment, the controller 280 provides no notification to the I/O device 281 when the remaining gas exhaust time is shorter than the threshold value stored in the memory 280c.

The controller 280 may be a special-purpose computer or a general-purpose computer. For example, the controller 280 according to the present embodiment can be configured in such a manner that an external memory 282 that stores the foregoing program is prepared, and then the program is installed in a general-purpose computer, using the external memory 282. Examples of the external memory 282 may include, but not limited to, magnetic tapes, magnetic disks such as a flexible disk and a hard disk, optical disks such as a CD and a DVD, magneto-optical disks such as an MO, and semiconductor memories such as a USB memory (a USB flash drive) and a memory card. The external memory 282 is not necessarily used for supplying the program to the computer. The program may be supplied without the external memory 282 by, for example, using a communication tool such as the Internet or a special-purpose line or receiving information from the host apparatus 270 via the transceiver 283. Alternatively, an instruction may be given to the controller 280, using the I/O device 281.

Each of the memory 280c and the external memory 282 is configured with a computer-readable recording medium. These memories will also be simply referred to as a recording medium. The term “recording medium” as used herein may refer to the memory 280c, the external memory 282, or both the memory 280c and the external memory 282.

### (Method of Manufacturing Semiconductor Device)

Next, a description will be given of steps of a method of manufacturing a semiconductor device. In the following, a description will be given of a film forming process of forming a SiO₂ film on a substrate 100. In the following description, the controller 280 controls the operation of each constituent of the substrate processing apparatus 200.

### (The Substrate Loading Step)

In the substrate processing apparatus 200 illustrated in FIG. 1, the gate valve 149 is opened, and the substrate 100 is loaded into the lower container 202b of the processing container 202 through the substrate loading/unloading port 148. The substrate 100 is mounted on the plurality of lifting pins 207. The lifting pins 207 pass through the through-holes 214 in the susceptor 212, and protrude from the surface of the susceptor 212. The gate valve 149 is then closed. Next, the susceptor 212 is lifted up, and the substrate 100 is mounted on the susceptor 212. The susceptor 212 then stops at the substrate processing position. Next, the lifting pins 207 retract into the through-holes 214 where the lifting pins 207 are not in contact with the substrate 100. The through-holes 214 in the susceptor 212 are thus closed with the lifting pins 207. The substrate 100 is in the state illustrated in FIG. 1.

In this state, as illustrated in FIGS. 1 and 3, the valves 252 of the gas supplier 240 are closed.

In the state illustrated in FIGS. 1 and 3, the pressure in each of the bypass pipe 249a and the processing gas supply pipe 243a is lower than the pressure of the processing gas from the processing gas supply source 243b and the pressure of the inert gas from the inert gas supply source 247b. In other words, the bypass pipe 249a is evacuated in advance by the second exhauster 263, and the processing gas supply pipe 243a is evacuated in advance by the first exhauster 262. Also in the state illustrated in FIGS. 1 and 3, the controller 280 drives the DP 278 and regulates the opening degree of the APC 261c to an opening degree set in advance. In addition, the controller 280 opens the valve 261b. In other words, the interior of the processing container 202 is evacuated.

### (A Processing Gas Supplying Step)

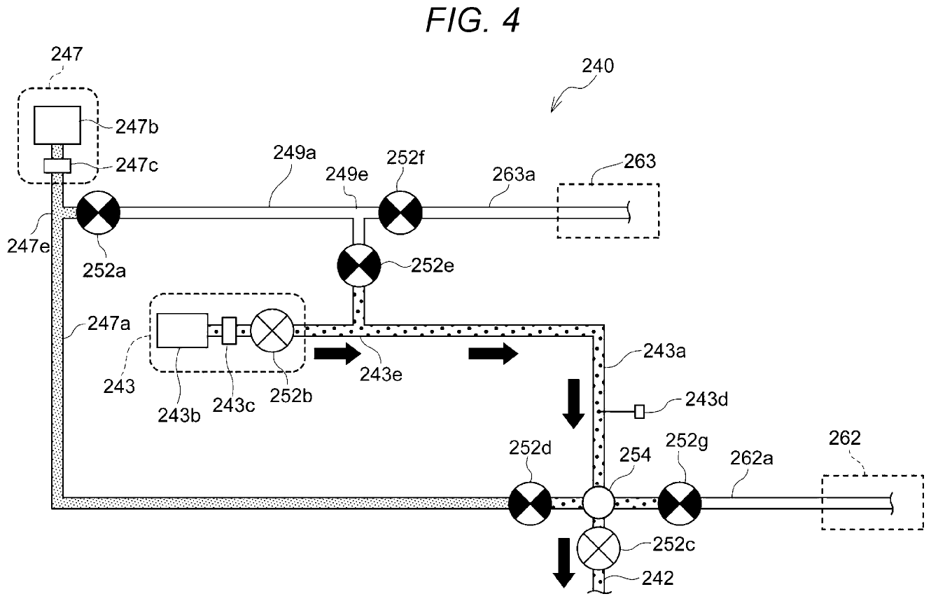

In a step of supplying the processing gas, as illustrated in FIG. 4, the controller 280 opens the second valve 252b and the third valve 252c. The processing gas is thus supplied from the processing gas supply source 243b of the processing gas supplier 243 into the processing container 202 through the processing gas supply pipe 243a.

### (A Substrate Processing Step)

Next, in a step of processing the substrate 100, as illustrated in FIG. 1, the controller 280 causes the shower head 230 to spray the processing gas onto the substrate 100 in the processing container 202. The controller 280 then maintains a state of the substrate 100 exposed to the processing gas by a time set in advance. A SiO₂ film is thus formed on the substrate 100.

### (A Inert Gas Purging Step)

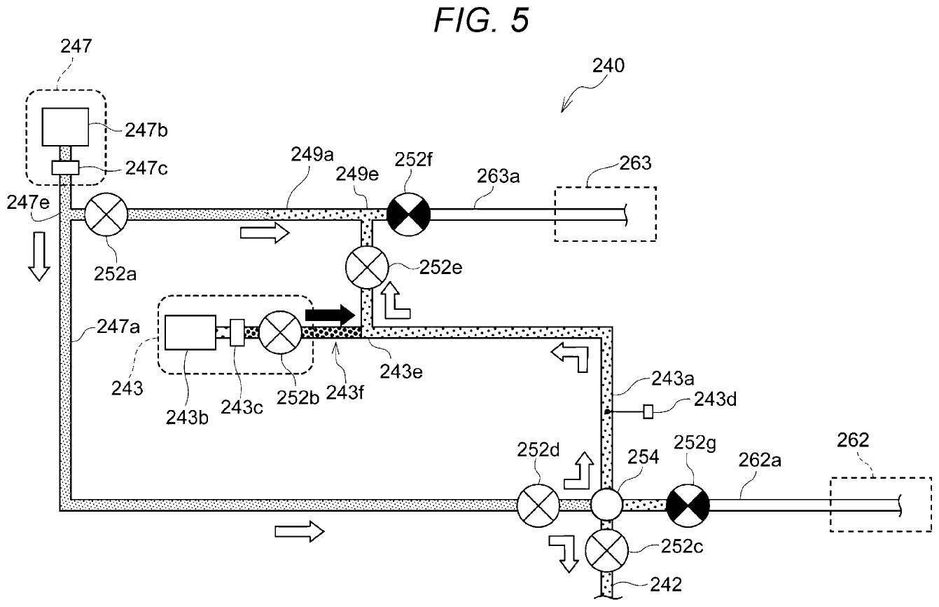

Next, as illustrated in FIG. 5, the controller 280 opens the first valve 252a, the fourth valve 252d, and the fifth valve 252e. The inert gas thus flows from the connector 254 into the processing container 202 through the common gas supply pipe 242. As a result, the gas in a space ranging from the connector 254 to the processing container 202 is purged with the inert gas.

In the present embodiment, as illustrated in FIG. 5, the controller 280 maintains an open state of the second valve 252b, thereby filling the processing gas supply pipe 243a ranging from the second valve 252b to the branch portion 243e, with the processing gas. The controller 280 thus forms a gas barrier 243f in the processing gas supply pipe 243a ranging from the second valve 252b to the branch portion 243e.

In the present embodiment, as described above, the pressure in the bypass pipe 249a is lower than the pressure of the inert gas before carrying out the step of processing the substrate 100. Therefore, the inert gas flows into the bypass pipe 249a via the first valve 252a. Likewise, the inert gas in the processing gas supply pipe 243a flows into the bypass pipe 249a via the fourth valve 252d. As a result, the pressure in the processing gas supply pipe 243a becomes lower than the pressure in the inert gas supply pipe 247a. Therefore, the inert gas flows from the connector 254 toward the upstream side of the processing gas supply pipe 243a. The gas in the processing gas supply pipe 243a is thus purged with the inert gas.

As illustrated in FIG. 5, the gas barrier 243f is formed in the processing gas supply pipe 243a ranging from the second valve 252b to the branch portion 243e. As illustrated in FIG. 5, moreover, the inert gas flows from the downstream side of the processing gas supply pipe 243a toward the branch portion 243e. Therefore, the pressure of the processing gas rises at the gas barrier 243f. As a result, the inert gas is hardly mixed with the processing gas in the processing gas supply pipe 243a ranging from the second valve 252b to the branch portion 243e.

### (A Remaining Gas Discharging Step)

Next, the controller 280 closes the second valve 252b to stop supply of the processing gas. After closing the second valve 252b, the controller 280 also closes the first valve 252a, the fourth valve 252d, and the fifth valve 252e to stop supply of the inert gas to the connector 254 and bypass pipe 249a.

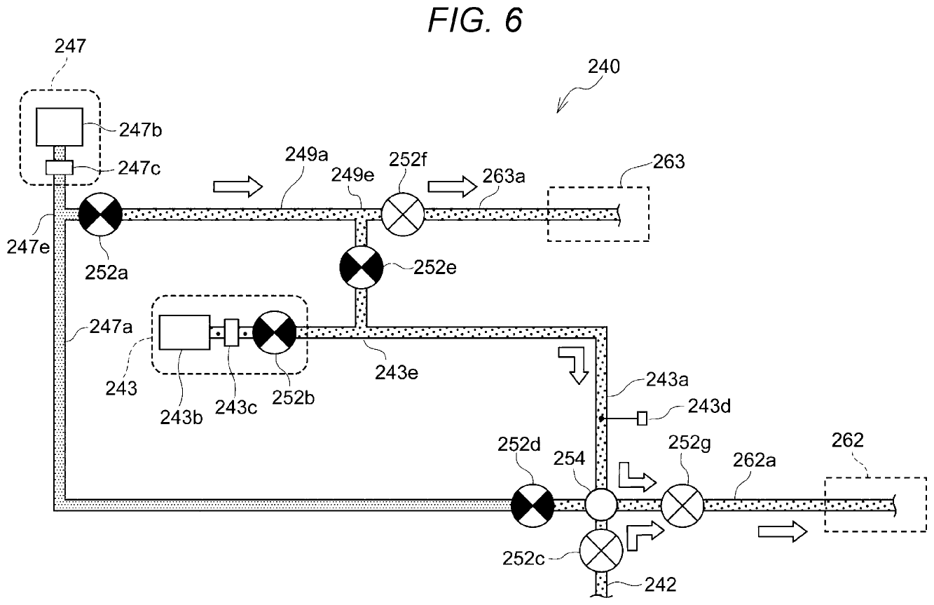

As illustrated in FIG. 6, the controller 280 opens the sixth valve 252f and the seventh valve 252g after closing the first valve 252a, the fourth valve 252d, and the fifth valve 252e. The controller 280 then causes the first exhauster 262 to discharge the remaining gas (i.e., the mixed gas of the processing gas with the inert gas) out of the processing gas supply pipe 243a and processing container 202. Moreover, the controller 280 causes the second exhauster 263 to discharge the remaining gas out of the bypass pipe 249a.

The controller 280 then closes the seventh valve 252g after discharging the remaining gas out of the processing gas supply pipe 243a (i.e., after determining that the concentration of the remaining gas is equal to or less than a threshold value set in advance). Moreover, the controller 280 closes the sixth valve 252f after discharging the remaining gas out of the bypass pipe 249a. It should be noted that the sixth valve 252f and the seventh valve 252g may be closed at different timings. In other words, after determining that the remaining gas is discharged out of the processing gas supply pipe 243a, the controller 280 may close the seventh valve 252g and proceed to the subsequent step even in a state in which the remaining gas still remains in the bypass pipe 249a.

### (The Substrate Unloading Step)

Next, the susceptor 212 and the plurality of lifting pins 207 move to the substrate transfer position, so that the substrate 100 is mounted on the lifting pins 207 protruding from the surface of the susceptor 212. Next, the gate valve 149 of the substrate processing apparatus 200 is opened, and the substrate 100 is unloaded from the processing container 202 through the substrate loading/unloading port 148. The gate valve 149 is then closed, and the substrate processing process ends. The substrate 100 thus unloaded is transferred to the subsequent process.

Substrates 100 are successively processed through the repetition of the foregoing steps.

In the foregoing the remaining gas discharging Step (hereinafter, simply referred to as the discharging step), the controller 280 opens the seventh valve 252g and starts to measure a remaining gas exhaust time. The controller 280 then compares the remaining gas exhaust time with the threshold value set in advance and stored in the memory 280c, to determine whether unusual exhaust has occurred. When determining that the unusual exhaust has occurred, the controller 280 causes the I/O device 281 to display information about the unusual exhaust.

Next, a description will be given of actions and effects of the substrate processing apparatus 200 according to the present embodiment.

### (Actions and Effects)

In the substrate processing apparatus 200 according to the present embodiment, the first exhauster 262 discharges the processing gas remaining in the processing gas supply pipe 243a out of the processing gas supply pipe 243a.

In the substrate processing apparatus 200 according to the present embodiment, the processing gas supply pipe 243a is provided with the first exhauster 262; therefore, the remaining gas in the processing gas supply pipe 243a is discharged without via the processing chamber, which reduces a cycle time in processing the substrate 100.

Therefore, the substrate processing apparatus 200 according to the present embodiment is capable of promptly discharging the processing gas remaining in the processing gas supply pipe 243a through which the processing gas is supplied to the processing chamber, as compared with a configuration that discharges the remaining gas via the processing chamber.

Also in the substrate processing apparatus 200 according to the present embodiment, the first exhauster 262 is located nearer to the processing container 202 than to the processing gas supplier 243 in the processing gas supply pipe 243a. Therefore, the substrate processing apparatus 200 according to the present embodiment facilitates discharging the remaining gas on the processing gas supply side of the shower head 230 in the processing container 202, in addition to the gas remaining in the processing gas supply pipe 243a.

Also in the substrate processing apparatus 200 according to the present embodiment, the first exhauster 262 includes the first processing gas exhaust pipe 262a connected to the processing gas supply pipe 243a. Therefore, the substrate processing apparatus 200 according to the present embodiment is capable of promptly discharging the remaining gas in the processing gas supply pipe 243a out of the processing gas supply pipe 243a through the first exhauster 262.

Also in the substrate processing apparatus 200 according to the present embodiment, the first processing gas exhaust pipe 262a is provided with the seventh valve 252g. Therefore, the substrate processing apparatus 200 according to the present embodiment is capable of controlling discharge of the remaining gas from the processing gas supply pipe 243a.

Also in the substrate processing apparatus 200 according to the present embodiment, the first valve 252a is made of a material capable of resisting a temperature of the processing gas. Therefore, the substrate processing apparatus 200 according to the present embodiment operates as usual even in a case where the processing gas increases the temperature of the first valve 252a.

Also in the substrate processing apparatus 200 according to the present embodiment, the first processing gas exhaust pipe 262a is made of a metal, and the inner wall of the first processing gas exhaust pipe 262a is subjected to anticorrosion processing. In the substrate processing apparatus 200 according to the present embodiment, therefore, the first processing gas exhaust pipe 262a resists corrosion owing to the processing gas.

The substrate processing apparatus 200 according to the present embodiment includes the sensor 243d that senses the remaining gas remaining in the processing gas supply pipe 243a. In addition, the controller 280 measures a remaining gas exhaust time during which the remaining gas is discharged out of the processing gas supply pipe 243a, and provides a notification about unusual exhaust when the remaining gas exhaust time is more than the threshold value set in advance.

In the substrate processing apparatus 200 according to the present embodiment, the sensor 243d senses the remaining gas, so that the controller 280 is capable of accurately measuring the remaining gas exhaust time. Therefore, the substrate processing apparatus 200 according to the present embodiment is capable of notifying an operator of discharge of the processing gas.

The substrate processing apparatus 200 according to the present embodiment includes the memory 280c that stores the threshold value. In addition, the controller 280 determines whether abnormal exhaust has occurred, by a comparison of the remaining gas exhaust time with the threshold value acquired from the memory 280c.

The substrate processing apparatus 200 according to the present embodiment avoids the operator from setting a wrong threshold value since the operator does not need to set the threshold value for the controller 280 every time.

Also in the substrate processing apparatus 200 according to the present embodiment, the memory 280c stores a history of the unusual exhaust in accordance with a notification about the unusual exhaust from the controller 280. Therefore, the substrate processing apparatus 200 according to the present embodiment allows the operator to recognize the unusual exhaust occurred in the past discharging step.

The substrate processing apparatus 200 according to the present embodiment includes the display that displays a state of the substrate 100 processed. In addition, the controller 280 causes the display to display the unusual exhaust in response to the notification about the unusual exhaust. Therefore, the substrate processing apparatus 200 according to the present embodiment allows the operator to easily check the unusual exhaust occurred in the discharging step.

Also in the substrate processing apparatus 200 according to the present embodiment, the controller 280 provides no notification when the remaining gas exhaust time is less than the threshold value. Therefore, the substrate processing apparatus 200 according to the present embodiment reduces a burden that is caused due to an unnecessary notification and is imposed on the operator in processing the substrate.

Also in the substrate processing apparatus 200 according to the present embodiment, the first exhauster 262 is capable of discharging the remaining gas that remains in the processing container 202 out of the processing container 202.

The common gas supply pipe 242, through which the processing gas is supplied, is provided on the upper side of the processing container 202. The processing gas from the common gas supply pipe 242 is uniformly supplied into the processing space 205 through the shower head 230 in the processing container 202. However, it is difficult to discharge the gas that is retained in the buffer space 234 of the shower head 230, out of the buffer space 234 through the processing space 205 in a short time. The first exhauster 262 provided near the processing container 202 is capable of discharging the remaining gas out of the shower head 230 in a shorter time than a configuration that discharges the remaining gas out of the processing container 202.

Also in the substrate processing apparatus 200 according to the present embodiment, the controller 280 is capable of controlling the first exhauster 262 so that the first exhauster 262 discharges the remaining gas out of the processing container 202. In the substrate processing apparatus 200 according to the present embodiment, therefore, the controller 280 achieves automatic discharge of the remaining gas in the processing container 202, which reduces a burden on the operator in processing the substrate.

In the method of manufacturing the semiconductor device according to the present embodiment, the first exhauster 262 discharges the processing gas that remains in the processing gas supply pipe 243a out of the processing gas supply pipe 243a.

In the method of manufacturing the semiconductor device according to the present embodiment, the processing gas supply pipe 243a is provided with the first exhauster 262; therefore, the remaining gas in the processing gas supply pipe 243a is discharged without via the processing chamber, which reduces the cycle time in processing the substrate 100.

Therefore, the method of manufacturing the semiconductor device according to the present embodiment is capable of promptly discharging the processing gas remaining in the processing gas supply pipe 243a through which the processing gas is supplied to the processing chamber, as compared with a method of manufacturing a semiconductor device, the method including discharging the remaining gas via the processing chamber.

Also in the method of manufacturing the semiconductor device according to the present embodiment, the first exhauster 262 is located nearer to the processing container 202 than to the processing gas supplier 243 in the processing gas supply pipe 243a. Also in the method of manufacturing the semiconductor device according to the present embodiment, the discharging step includes discharging, by the first exhauster 262, the remaining gas remaining in the processing container 202 out of the processing container 202.

The method of manufacturing the semiconductor device according to the present embodiment facilitates discharging the remaining gas on the processing gas supply side of the shower head 230 in the processing container 202, in addition to the gas remaining in the processing gas supply pipe 243a.

The program according to the present embodiment causes the controller 280 to perform supplying the processing gas with which the substrate 100 is processed, from the processing gas supplier 243 connected to the processing gas supply pipe 243a, to the processing container 202 in which the substrate 100 is processed. The program according to the present embodiment also causes the controller 280 to perform processing the substrate 100 in the processing container 202. The program according to the present embodiment also causes the controller 280 to perform discharging, by the first exhauster 262 provided on the processing gas supply pipe 243a, the remaining gas in the processing gas supply pipe 243a out of the processing gas supply pipe 243a.

In the program according to the present embodiment, the first exhauster 262 discharges the processing gas remaining in the processing gas supply pipe 243a out of the processing gas supply pipe 243a.

In the substrate processing apparatus 200 according to the present embodiment, as described above, the processing gas supply pipe 243a is provided with the first exhauster 262; therefore, the remaining gas in the processing gas supply pipe 243a is discharged without via the processing chamber, which reduces the cycle time in processing the substrate 100.

Therefore, the program according to the present embodiment is capable of promptly discharging the processing gas remaining in the processing gas supply pipe 243a, through which the processing gas is supplied to the processing chamber, as compared with a program for discharging the remaining gas via the processing chamber.

The program according to the present embodiment also causes the controller 280 to perform, in the discharging, further discharging, by the first exhauster 262, the remaining gas in the processing container 202 out of the processing container 202.

Therefore, the program according to the present embodiment facilitates discharging the remaining gas on the processing gas supply side of the shower head 230 in the processing container 202, in addition to the gas remaining in the processing gas supply pipe 243a.

### (Modifications)

In the foregoing description, the first exhauster 262 is located nearer to the processing container 202 than to the processing gas supplier 243 in the processing gas supply pipe 243a; however, the substrate processing apparatus 200 according to the present embodiment is not limited thereto. For example, the first exhauster 262 may be located nearer to the processing gas supplier 243 than to the processing container 202 as long as the first exhauster 262 is capable of discharging the remaining gas out of the processing gas supply 243a.

Also in the foregoing description, the first exhauster 262 includes the first processing gas exhaust pipe 262a; however, the substrate processing apparatus 200 according to the present embodiment is not limited thereto. For example, the first exhauster 262 may discharge the remaining gas externally without the first processing gas exhaust pipe 262a as long as the remaining gas that remains in the processing gas supply pipe 243a can be discharged out of the processing gas supply pipe 243a.

Also in the foregoing description, the processing gas supply pipe 243a is provided with the sensor 243d; however, the substrate processing apparatus 200 according to the present embodiment is not limited thereto. For example, the controller 280 may determine that the remaining gas has been discharged out of the processing gas supply pipe 243a, when the measured remaining gas exhaust time is more than the threshold value set in advance.

Also in the foregoing description, the controller 280 provides the notification about the unusual exhaust when the remaining gas exhaust time is more than the threshold value set in advance; however, the substrate processing apparatus 200 according to the present embodiment is not limited thereto. For example, the controller 280 does not necessarily provide a notification about unusual exhaust.

Also in the foregoing description, the controller 280 causes the memory 280c to store a history of unusual exhaust each time unusual exhaust occurs; however, the substrate processing apparatus 200 according to the present embodiment is not limited thereto. For example, the controller 280 does not necessarily cause the memory 280c to store a history of unusual exhaust even when unusual exhaust occurs.

Also in the foregoing description, the controller 280 causes the I/O device 281 to display unusual exhaust when the unusual exhaust occurs; however, the substrate processing apparatus 200 according to the present embodiment is not limited thereto. For example, the controller 280 does not necessarily cause the I/O device 281 to display unusual exhaust even when the unusual exhaust occurs.

Also in the foregoing description, the first exhauster 262 is capable of discharging the remaining gas out of the processing chamber; however, the substrate processing apparatus 200 according to the present embodiment is not limited thereto. For example, the first exhauster 262 does not necessarily discharge the remaining gas out of the processing chamber as long as the remaining gas that remains in the processing gas supply pipe 243a can be discharged out of the processing gas supply pipe 243a.

Also in the modifications, the processing gas remaining in the processing gas supply pipe 243a, through which the processing gas is supplied to the processing container 202, can be discharged promptly as compared with a configuration in which the remaining gas is discharged via the processing chamber. The foregoing embodiment and modifications may be used in combination as appropriate. Processing procedures and processing conditions in such a combination may be similar to, for example, processing procedures and processing conditions in the foregoing embodiment and modifications.

The foregoing embodiment has described an exemplary case where a film is formed using a single-type substrate processing apparatus configured to process one or several substrates at a time. However, the present disclosure is not limited to the foregoing embodiment. For example, the present disclosure is suitably applicable to a case where a film is formed using a batch-type substrate processing apparatus configured to process a plurality of substrates at a time. The foregoing embodiment has also described an exemplary case where a film is formed using a substrate processing apparatus including a cold wall-type processing furnace. However, the present disclosure is not limited to the foregoing embodiment. For example, the present disclosure is suitably applicable to a case where a film is formed using a substrate processing apparatus including a hot wall-type processing furnace.

These substrate processing apparatuses are capable of performing the respective processes by the similar processing procedures and on the similar processing conditions to the processing procedures and processing conditions in the foregoing embodiment and modifications, and are capable of producing similar effects to the effects in the foregoing embodiment and modifications.

Although one or more embodiments of the present disclosure have been described with reference to the accompanying drawings, it is apparent that a person who has ordinary knowledge in the technical field to which the present disclosure pertains can conceive various variations and applications within the scope of the technical idea recited in the claims, and it is naturally understood that these variations and applications also belong to the technical scope of the present disclosure.

According to the present disclosure, an adverse effect of a processing gas that remains in a processing gas supply pipe can be reduced in a substrate processing apparatus for processing a substrate, using the processing gas.

What is claimed is:

1. A substrate processing apparatus comprising:
a processing container in which a substrate is processed;
a processing gas supplier that supplies a processing gas with which the substrate is processed;
a processing gas supply pipe that is connected to the processing gas supplier and the processing container and through which the processing gas is supplied to the processing container;
an exhauster that is provided on the processing gas supply pipe; and
a controller for controlling the exhauster to discharge a remaining gas in the processing gas supply pipe out of the processing gas supply pipe.

2. The substrate processing apparatus according to claim 1, wherein
the exhauster is located nearer to the processing container than to the processing gas supplier in the processing gas supply pipe.

3. The substrate processing apparatus according to claim 1, wherein
the exhauster includes a processing gas exhaust pipe connected to the processing gas supply pipe.

4. The substrate processing apparatus according to claim 3, wherein
the processing gas exhaust pipe includes a valve that opens and closes the processing gas exhaust pipe.

5. The substrate processing apparatus according to claim 4, wherein
the valve is made of a material capable of resisting a temperature of the processing gas.

6. The substrate processing apparatus according to claim 3, wherein
the processing gas exhaust pipe is made of a metal, and includes an inner wall subjected to anticorrosion processing.

7. The substrate processing apparatus according to claim 1, wherein
the controller measures a remaining gas exhaust time during which the remaining gas is discharged out of the processing gas supply pipe, and provides a notification about unusual exhaust when the remaining gas exhaust time is more than a threshold value set in advance.

8. The substrate processing apparatus according to claim 7, further comprising
a memory that stores the threshold value,
wherein
the controller determines whether the unusual exhaust occurs, by a comparison of the remaining gas exhaust time with the threshold value acquired from the memory.

9. The substrate processing apparatus according to claim 8, wherein
the memory stores a history of the unusual exhaust in response to the notification about the unusual exhaust from the controller.

10. The substrate processing apparatus according to claim 7, further comprising
a display,
wherein
the controller controls the display to display the unusual exhaust in response to the notification about the unusual exhaust.

11. The substrate processing apparatus according to claim 7, wherein
the controller provides no notification when the remaining gas exhaust time is less than the threshold value.

12. The substrate processing apparatus according to claim 1, wherein
the exhauster is capable of discharging a remaining gas in the processing container out of the processing container.

13. The substrate processing apparatus according to claim 12, wherein
the controller controls the exhauster to discharge the remaining gas in the processing container out of the processing container.

14. A method of manufacturing a semiconductor device, comprising:
supplying a processing gas with which a substrate is processed to a substrate and processing the substrate, wherein the processing gas is supplied from a processing gas supplier connected to a processing gas supply pipe, to a processing container in which the substrate is processed; and
discharging, by an exhauster on the processing gas supply pipe, a remaining gas in the processing gas supply pipe out of the processing gas supply pipe.

15. The method according to claim 14, wherein
the exhauster is located nearer to the processing container than to the processing gas supplier in the processing gas supply pipe, and
the discharging further includes discharging, by the exhauster, a remaining gas in the processing container out of the processing container.

16. A non-transitory computer-readable recording medium storing a program that causes, by a computer, a substrate processing apparatus to perform a process comprising:
supplying a processing gas with which a substrate is processed to a substrate and processing the substrate, wherein the processing gas is supplied from a processing gas supplier connected to a processing gas supply pipe, to a processing container in which the substrate is processed; and
discharging, by an exhauster provided on the processing gas supply pipe, a remaining gas in the processing gas supply pipe out of the processing gas supply pipe.

17. The non-transitory computer-readable recording medium according to claim 16, wherein
the exhauster is located nearer to the processing container than to the processing gas supplier in the processing gas supply pipe, and
the discharging further includes discharging, by the exhauster, a remaining gas in the processing container out of the processing container.
